(19) United States
(12) Patent Application Publication
(10) Pub. No.: US 2006/0286698 A1
(43) Pub. Date: Dec. 21, 2006

(54) Electro-optical device, method of manufacturing the same, and electronic apparatus

(75) Inventor: Hisaki Kurashina, Matsumoto-shi (JP)

Correspondence Address: ADVANTEDGE LAW GROUP, LLC, 1928 E. COBBLESTONE RD., SUITE 100, SPRINGVILLE, UT, 84663, US

(73) Assignee: Seiko Epson Corporation, Shinjuku-ku (JP)

(21) Appl. No.: 11/430,020

(22) Filed: May 8, 2006

(30) Foreign Application Priority Data
Jun. 17, 2005 (JP) 2005-178313
Aug. 3, 2005 (JP) 2005-225881

(51) Int. Cl. H01L 21/00; G02F 1/136; H01L 33/00

(52) U.S. Cl. 438/29; 349/48; 257/79

(57) ABSTRACT

An electro-optical device includes: a substrate; a plurality of data lines which are formed on the substrate; a plurality of scanning lines which are arranged on the substrate so as to intersect the plurality of data lines; a plurality of pixel electrodes which are provided on the substrate so as to correspond to intersections of the plurality of data lines and the plurality of scanning lines; a plurality of transistors which are formed on the substrate so as to be electrically connected to the plurality of pixel electrodes; a plurality of storage capacitors each of which is provided above the transistor so as not to be in contact with the transistor in plan view and temporally stores a pixel signal supplied to the pixel electrode through the data line and the transistor. In the electro-optical device, a separating region between adjacent storage capacitors among the plurality of storage capacitors is arranged above the transistor.

### BACKGROUND

1. Technical Field

The present invention relates to an electro-optical device, such as a liquid crystal display device including transistors, each having a semiconductor layer which is composed of, for example, a polysilicon film and is subjected to a hydrogen treatment, to a method of manufacturing the electro-optical device, and to an electronic apparatus equip with the electro-optical device.

2. Related Art

In this type of electro-optical device, a polycrystalline semiconductor layer formed of, for example, polysilicon is sometimes used as a semiconductor layer of a thin film transistor (hereinafter, referred to as a TFT) provided in a pixel portion. In the polycrystalline semiconductor layer, a high-reactivity bond, such as a dangling bond, may be included in crystal defects at the boundary between crystal grains or in a crystal grain. The dangling bond causes the semiconductor layer to be chemically unstable, resulting in the deterioration of the characteristics of the transistor.

Meanwhile, in this type of electro-optical device, in order to prevent an optical current from leaking from the TFT, a storage capacitor for temporally storing an image signal supplied to the pixel electrode of the liquid crystal display device is intentionally formed on the TFT so as to shield light incident on the TFT, thereby preventing a display defect, such as a dot defect on a displayed image.

The storage capacitor has a function of shielding light incident on the TFT to reduce an optical leakage current, but hinders a process of performing a hydrogen treatment on the polysilicon film to effectively remove the dangling bond. A light shielding member other than the storage capacitor, such as a light shielding film formed above the transistor, can be used to reduce the optical leakage current, without a large change in the structure of an electro-optical device and manufacturing processes thereof. However, once the storage capacitor is formed above the transistor so as to overlap the transistor in plan view, the storage capacitor makes it difficult to perform the hydrogen treatment on the semiconductor layer of the transistor, from the viewpoint of the design and the manufacturing process.

In order to solve these problems, JP-A-2004-103732, JP-A-2004-140329, and JP-A-2004-140330 disclose a technique for checking the design of the storage capacitor to enable the hydrogen treatment. For example, JP-A-2004-103732 discloses a technique for reducing the thickness of a nitride film of the storage capacitor so as not to hinder the hydrogen treatment on the semiconductor film. JP-A-2004-140329 and JP-A-2004-140330 disclose a technique for forming an opening in the nitride film of the storage capacitor and for performing, through the opening, the hydrogen treatment on the semiconductor layer formed below the opening.

However, the hydrogen treatment is hindered by a capacitor electrode arranged above the transistor as well as a nitride film, which is a dielectric film of a capacitor insulating film. JP-A-2004-103732, JP-A-2004-140329, and JP-A-2004-140330 disclose measures to overcome a difficulty in performing the hydrogen treatment due to the capacitor insulating film, but do not disclose measures to overcome a difficulty in performing the hydrogen treatment due to the capacitor electrode. Therefore, JP-A-2004-103732, JP-A-2004-140329, and JP-A-2004-140330 do not disclose sufficient measures to overcome a difficult in performing the hydrogen treatment. For example, polysilicon used for the capacitor electrode has a low hydrogen transmitting property and a strong hydrogen absorbing property. Therefore, when the polysilicon film is arranged above the transistor, it hinders the hydrogen treatment. In order to overcome the difficulty in performing the hydrogen treatment, it is necessary that an opening be formed in the capacitor electrode arranged above the transistor (JP-A-2004-140329 and JP-A-2004-140330 disclose a structure in which an opening portion is formed in only the upper capacitor electrode to correspond to an opening of the capacitor insulating film such the upper and lower capacitor electrodes formed above and below the opening of the capacitor insulating film are not electrically connected to each other, but it is also necessary to form an opening in the lower capacitor electrode).

When the openings are formed in the upper and lower capacitor electrodes arranged above and below the transistor, yield may be lowered due to a complicated pattern, and the capacitance of the storage capacitor may be lowered due to the removal of a part of the capacitor.

### SUMMARY

An advantage of some aspects of the invention is that it provides an electro-optical display device capable of easily performing a hydrogen treatment on a semiconductor layer even after a storage capacitor is formed on the semiconductor layer to prevent characteristics of a transistor provided in a pixel portion, such as a TFT, from being deteriorated, a method of manufacturing the electro-optical device, and an electronic apparatus equipped with the electro-optical device.

According to an aspect of the invention, an electro-optical device includes: a substrate; a plurality of data lines which are formed on the substrate; a plurality of scanning lines which are arranged on the substrate so as to intersect the plurality of data lines; a plurality of pixel electrodes which are provided on the substrate so as to correspond to intersections of the plurality of data lines and the plurality of scanning lines; a plurality of transistors which are formed on the substrate so as to be electrically connected to the plurality of pixel electrodes; a plurality of storage capacitors each of which is provided above the transistor so as not to be in contact with the transistor in plan view and temporally stores a pixel signal supplied to the pixel electrode through the data line and the transistor. In the electro-optical device, a separating region between adjacent storage capacitors among the plurality of storage capacitors is arranged above the transistor.

According to the electro-optical device of this aspect, since the storage capacitor is formed above the transistor so as not to be in contact with the transistor in plan view, it is possible to reliably perform the hydrogen treatment on the semiconductor layer of the transistor through the storage capacitor. In addition, the hydrogen treatment can be performed on the transistor after the storage capacitor is formed above the transistor, which makes it possible to remove factors of deteriorating characteristics of the transistor, such as a dangling bond. This structure makes it possible to improve the characteristics of the transistor without a change in the structure of an electro-optical device through a complicated process and a large change in the manufacturing process of the electro-optical device. Here, the term ‘not overlapping in plan view’ means that the storage capacitor does not overlap the transistor, as viewed from the upper side of the storage capacitor. More specifically, the term means that hydrogen is supplied from the upper side of the storage capacitor to the transistor without being hindered by the storage capacitor. In this aspect, the term ‘so as not to be in contact with the transistor’ includes a structure in which the storage capacitor does not completely overlap the transistor and a structure in which the storage capacitor deviates from the transistor by an extent not preventing the hydrogen treatment.

According to the electro-optical device of this aspect, it is possible to perform the hydrogen treatment on the transistor after the storage capacitor is formed, without a large change in the structure of the electro-optical device and manufacturing processes thereof. Thus, it is possible to reliably prevent the capacitance of the storage capacitor from being lowered, without a large change in the structure of the electro-optical device. In addition, according to this aspect, it is possible to manufacture an electro-optical device having a high display quality with a high yield.

In the electro-optical device according to this aspect, it is preferable that the separating region be arranged above at least a channel region of the transistor.

According to this structure, it is possible to perform the hydrogen treatment on the channel region through the separating portion.

In the electro-optical device according to this aspect, it is preferable that the separating region be arranged above at least the channel region and an LDD region of the transistor.

According to this structure, it is possible to perform the hydrogen treatment on the channel region and the LDD region through the separating portion.

In the electro-optical device according to this aspect, preferably, each of the storage capacitors includes a first electrode formed above the transistor, a dielectric film formed on the first layer, and a second layer formed on the dielectric film, and at least the first and second electrodes of the first electrode, the second electrode, and the dielectric film are formed so as not to be in contact with the transistor in plan view.

According to this structure, the first electrode and the second electrode are formed so as not to be in contact with the transistor, which makes it possible to remove a main factor of hindering the hydrogen treatment. That is, the storage capacitor functioning as an actual capacitive element is provided so as not to be in contact with the transistor. More specifically, the first electrode and the second electrode are composed of, for example, conductive polysilicon films or conductive films, such as metal films, which transmit little hydrogen, and these conductive films are generally formed of a material transmitting little hydrogen and with a thickness transmitting little hydrogen. Since the first electrode and the second electrode composed of the conductive films are formed so as not to be in contact with the transistor, it is possible to prevent the storage capacitor formed above the transistor from extending to a region where the hydrogen treatment is hindered, without excessively reducing the capacitance of the storage capacitor.

In the electro-optical device according to this aspect, preferably, the second electrode extends along the scanning line so as to be provided for all of the plurality of storage capacitors, and a portion of the second electrode is cut out so that the second electrode does not overlap the transistor in plan view.

According to this structure, since the cut-out portion is provided in the second electrode, the hydrogen treatment on the transistor is not hindered by the second electrode. In addition, it is possible to perform the hydrogen treatment on the transistor after the second electrode is formed, without an excessive reduction in the area of the second electrode and a large change in the plan-view shape of the second electrode.

In the electro-optical device according to this aspect, preferably, the second electrode extends along the scanning line so as to be provided for all of the plurality of storage capacitors, and the second electrode has a first opening portion which is formed so as to overlap the transistor in plan view.

According to this structure, it is possible to perform, through the first opening portion, the hydrogen treatment on the transistor provided below the first opening portion. The first opening portion may be formed in only a region having a sufficient area to perform the hydrogen treatment on the semiconductor layer of the transistor. In addition, the first opening portion makes it possible to prevent the area of a portion of the second electrode actually forming the storage capacitor from being excessively reduced. Thus, it is possible to prevent a reduction in the capacitance of the storage capacitor due to the first opening portion formed in the second electrode. Further, since the second electrode is common to a plurality of storage capacitors, it is possible to collectively form the second electrodes so as to extend to a plurality of pixel regions, and to simplify a manufacturing process, as compared with a structure in which the second electrode is patterned to be individually formed in each storage capacitor.

In the electro-optical device according to this aspect, preferably, the second electrode is a pixel-potential-side capacitor electrode, and the separating portion of the capacitor electrode is arranged above the transistor, so that the transistor is exposed through the storage capacitor.

According to this structure, since the separating portion of the pixel potential side capacitor electrode is arranged above the transistor, a simpler pattern and a higher yield are obtained, and the capacitance of the storage capacitor is not reduced, as compared with a structure in which the opening portion is separately formed from the separating portion.

According to this aspect, preferably, the electro-optical device further includes wiring portions which are formed above the storage capacitors on the substrate so as to be electrically connected to the second electrodes. Preferably, each of the wiring portions is formed so as to extend on the storage capacitor, after a hydrogen treatment is performed on a semiconductor layer of the transistor from the upper side of the storage capacitor.

According to this structure, for example, when the wiring portion is formed so as to hinder the hydrogen treatment on the transistor, the shape of the wiring portion does not have an effect on the performance of the transistor since the hydrogen treatment is completely performed on the semiconductor layer before the wiring portion is formed.

In addition, according to this structure, since the wiring portion is formed after the hydrogen treatment is performed on the semiconductor layer of the transistor, the wiring portion can be formed so as to shield light incident on the transistor. Therefore, it is possible to improve the characteristics of the transistor by using the hydrogen treatment and to reduce an optical leakage current.

In the electro-optical device according this aspect, it is preferable that the dielectric film be formed so as not to be in contact with the transistor in plan view.

According to this structure, the dielectric film may extend onto the transistor, or it may be formed so as not to be in contact with the transistor, since the hindrance of the dielectric film on the hydrogen treatment is relatively less than that of the first and second electrodes on the hydrogen treatment. More specifically, for example, when the hydrogen treatment is performed through the dielectric film, such as a silicon oxide film or an oxide film obtained by performing a high-temperature treatment on a silicon nitride film, a sufficient amount of hydrogen may not be supplied to the transistor below the dielectric film. Therefore, in order to effectively perform the hydrogen treatment on the transistor, it is preferable that the dielectric film be formed so as not to be in contact with the transistor.

In the electro-optical device according to this aspect, it is preferable that the dielectric film be physically separated between the storage capacitors so as not to overlap the transistor in plan view.

According to this structure, it is possible to perform the hydrogen treatment on the transistor formed below the storage capacitor, without being hindered by the dielectric film. Here, the term ‘physically’ means that the dielectric film is individually formed in a plurality of storage capacitors; and that the dielectric film is collectively formed and is then patterned in a predetermined shape, so that it is provided in each storage capacitor. In addition, the term also means that the dielectric film is separated between the storage capacitors. A region between the dielectric films separated in this way is arranged above the transistor, and thus the hydrogen treatment can be performed on the transistor through the region.

In the electro-optical device according to this aspect, preferably, the dielectric film extends on the substrate so as to be provided for all of the plurality of storage capacitors, and the dielectric film has a second opening portion which is formed so as to overlap the transistor in plan view.

According to this structure, it is possible to perform the hydrogen treatment on the transistor, without restrictions on a material forming the dielectric film and a method of forming the dielectric film. More specifically, even when the first electrode, the dielectric film, and the second electrode are annealed at a high temperature where hydrogen is exhausted from the semiconductor layer of the transistor, it is possible to perform the hydrogen treatment on the semiconductor layer after the storage capacitor is formed. Thus, it is possible to prevent characteristics of the transistor from being deteriorated.

According to another aspect of the invention, a method of manufacturing an electro-optical device includes: forming a plurality of data lines and a plurality of scanning lines on a substrate so as to intersect each other; forming a plurality of pixel electrodes on the substrate so as to correspond to intersections of the plurality of data lines and the plurality of scanning lines; forming a plurality of transistors on the substrate so as to be electrically connected to the plurality of pixel electrodes; and forming a plurality of storage capacitors, each temporally storing an image signal supplied to the pixel electrode through the data line and the transistor, above the transistors so as not to be in contact with the transistors in plan view. In the method, in the forming of the storage capacitors, a first electrode, a dielectric film, and a second electrode are sequentially formed above each of the transistors to form the storage capacitor, and the first electrode and the second electrode are formed so as not to be in contact with the transistor in plan view.

According to the method of manufacturing an electro-optical device of this aspect, similar to the electro-optical device according to the above-mentioned aspect, it is possible to perform the hydrogen treatment on the transistor after the storage capacitor is formed, without a large change in the structure of the electro-optical device and the manufacturing process thereof, and to prevent the capacitance of the storage capacitor from being lowered without a large change in the structure of the device. In addition, according to the method of manufacturing an electro-optical device of this aspect, it is possible to manufacture an electro-optical device having a high display quality at a high yield.

In the method of manufacturing an electro-optical device according to this aspect, preferably, the forming of the storage capacitors includes annealing the first electrode, the dielectric film, and the second electrode at a temperature of 350° C. or more. Preferably, after the annealing, a hydrogen treatment is performed on a semiconductor layer of the transistor from the upper side of the storage capacitor.

According to the method of manufacturing an electro-optical device of this aspect, it is possible to perform the hydrogen treatment on the transistor, without restrictions on a material forming the dielectric film and a method of forming the dielectric film. More specifically, even when the first electrode, the dielectric film, and the second electrode are annealed at a high temperature where hydrogen is exhausted from the semiconductor layer of the transistor, it is possible to perform the hydrogen treatment on the semiconductor layer after the storage capacitor is formed. Thus, it is possible to prevent characteristics of the transistor from being deteriorated.

According to still another aspect of the invention, an electronic apparatus includes the above-mentioned electro-optical device.

According to the electronic apparatus of this aspect, it is possible to realize various electronic apparatuses, such as a projection-type display apparatus capable of displaying a high-quality image, a television, a cellular phone, an electronic organizer, a word processor, a view-finder-type or monitor-direct-view-type videotape recorder, a workstation, a television phone, a POS terminal, and apparatuses equipped with touch panels. The electro-optical device of the above-mentioned aspect can be applied to an electrophoresis apparatus, such as an electronic paper, a field emission display apparatus, a conduction electron-emitter display apparatus, and a DLP (digital light processing) apparatus. In addition, according to this aspect, it is possible to provide, for example, an LCOS (liquid crystal on silicon) display device, which is an example of a reflective liquid crystal display device.

The effects and advantages of the invention can be apparent from the following description of embodiments.

### BRIEF DESCRIPTION OF THE DRAWINGS

The invention will be described with reference to the accompanying drawings, wherein like numbers refer to like elements.

FIG. 1 is a plan view illustrating the overall structure of an electro-optical device according to an embodiment of the invention.

FIG. 2 is a cross-sectional view taken along the line II-II of FIG. 1.

FIG. 3 is an equivalent circuit diagram illustrating various elements and wiring lines of a plurality of pixel portions.

FIG. 4 is a plan view illustrating a plurality of pixel groups adjacent to each other on a TFT array substrate.

FIG. 5 is a cross-sectional view taken along the line V-V of FIG. 4.

FIG. 6 is a plan view illustrating a structure (a first modification) above a TFT 30 according to the embodiment.

FIG. 7 is a cross-sectional view illustrating a structure (a second modification) above the TFT 30 according to the embodiment.

FIGS. 8A to 8C are cross-sectional views illustrating manufacturing processes (part 1).

FIG. 9 is a cross-sectional view illustrating the manufacturing process (part 2).

FIG. 10 is a plan view illustrating a plurality of pixel groups adjacent to each other on a TFT array substrate having, for example, data lines, scanning lines, and pixel electrodes formed thereon, and shows only the structure of a lower portion (a portion below a member (storage capacitor) represented by reference numeral 70 in FIG. 12).

FIG. 11 is a plan view illustrating a plurality of pixel groups adjacent to each other on the TFT array substrate having, for example, the data lines, the scanning lines, and the pixel electrodes formed thereon, and shows only the structure of an upper portion (a portion above the member (storage capacitor) represented by reference numeral 70 in FIG. 12).

FIG. 12 is a cross-sectional view taken along the line XII-XII when FIG. 10 and FIG. 11 overlap each other.

FIG. 13 is a plan view illustrating a modification corresponding to FIG. 10.

FIG. 14 is a plan view illustrating the structure of a projector, which is an example of an electronic apparatus to which the electro-optical device is applied.

FIG. 15 is a plan view illustrating the structure of a personal computer, which is an example of an electronic apparatus to which the electro-optical device is applied.

FIG. 16 is a plan view illustrating the structure of a cellular phone, which is an example of an electronic apparatus to which the electro-optical device is applied.

### DESCRIPTION OF EXEMPLARY EMBODIMENTS

Hereinafter, an electro-optical device, a method of manufacturing an electro-optical device, and an electronic apparatus according to preferred embodiments of the invention will be described in detail with reference to the accompanying drawings. In first and second embodiments, a liquid crystal display device is used as an example of an electro-optical device and a method of manufacturing the same according to the invention.

### First Embodiment

(Overall Structure of Electro-Optical Device)

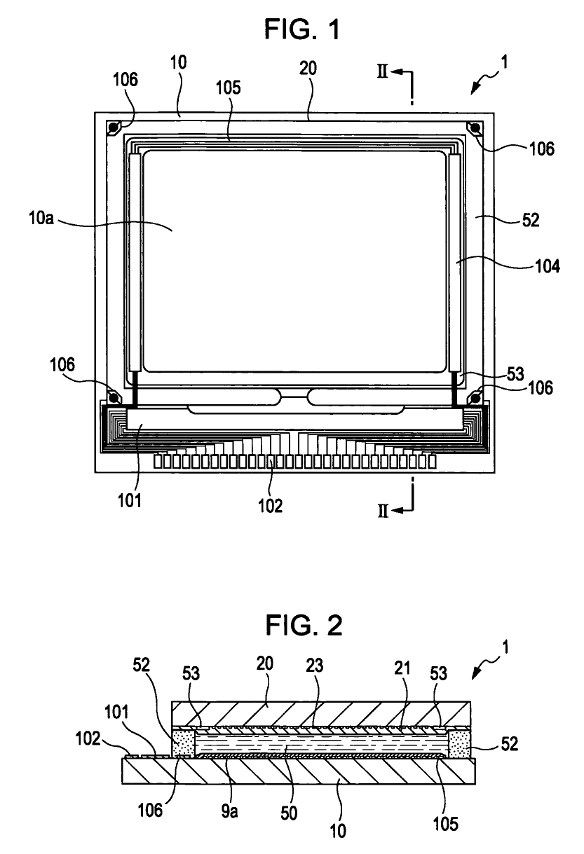

First, the overall structure of a liquid crystal display device which has a driving circuit integrated therein and is driven by a TFT active matrix driving method, which is an example of the electro-optical device according to this embodiment, will be described below with reference to FIGS. 1 and 2. FIG. 1 is a plan view illustrating a TFT array substrate having various components formed thereon of the electro-optical device, as viewed from a counter substrate. FIG. 2 is a cross-sectional view taken along the line II-II of FIG. 1.

In FIGS. 1 and 2, a liquid crystal display device 1 includes a TFT array substrate 10 and a counter substrate 20 arranged opposite to the TFT array substrate 10. A liquid crystal layer 20 is interposed between the TFT array substrate 10 and the counter substrate 20, and the TFT array substrate 10 and the counter substrate 20 are bonded to each other with a sealing member 52 interposed therebetween. The sealing member 52 is provided in a sealing region which is arranged in the periphery of an image display region 10a.

A frame-shaped light shielding film 53 for defining a frame-shaped region of the image display region 10a is provided on the counter substrate 20 so as to be arranged in parallel to the inside of the sealing region where the sealing member 52 is provided. However, a portion of or the entire frame-shaped light shielding film 53 may be provided on the TFT array substrate 10 as an integrated light shielding film. In this embodiment, a peripheral region is provided in the periphery of the image display region 10a. In other words, particularly, a region arranged outside the frame-shaped light shielding film 53 on the center of the TFT array substrate 10 is defined as the peripheral region. In a portion of the peripheral region disposed outside the sealing region in which the sealing member 52 is provided, a data line driving circuit 101 and external circuit connecting terminals 102 are provided along one side of the TFT array substrate 10. Further, a plurality of wiring lines 105 are provided to connect two scanning line driving circuits 104 which are provided at both sides of the image display region 10a. Vertical connecting members 106 for electrically connecting the TFT array substrate 10 and the counter substrate 10 are provided at four corners of the counter substrate 20.

In FIG. 2, for example, pixel switching TFTs and wiring lines, such as scanning lines and data lines, are formed on the TFT array substrate 10 to form pixel electrodes 9a, and an alignment film is formed thereon. On the other hand, a counter electrode 21 and a lattice-shaped or stripe-shaped light shielding film 23 are formed on the counter substrate 20, and an alignment film is formed on the uppermost layer of the counter substrate 20.

(Detailed Structure of Pixel Portion)

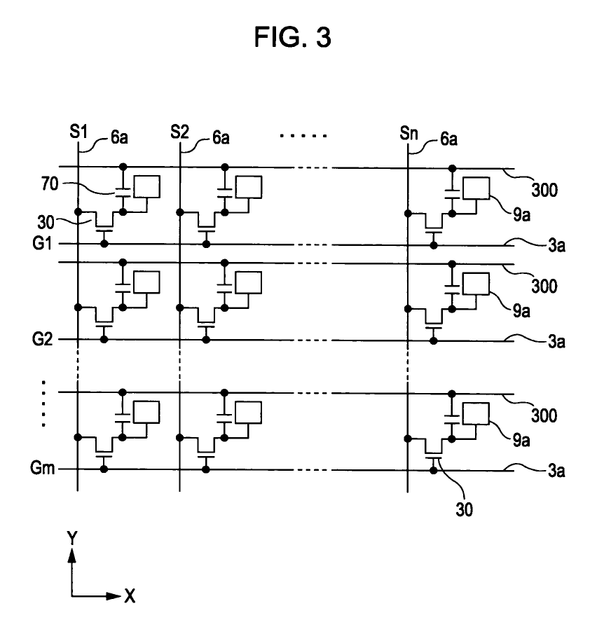

Next, the structure of a pixel portion of the liquid crystal display device 1 will be described with reference to FIGS. 3 to 5.

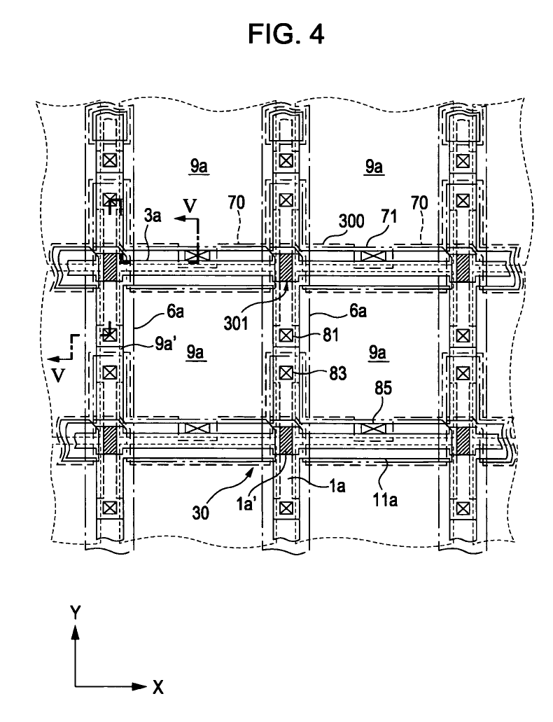

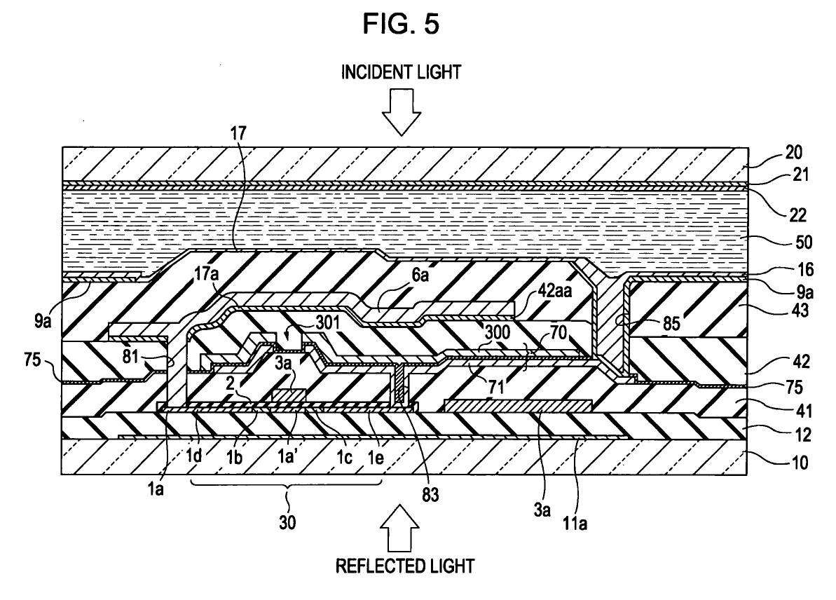

FIG. 3 is an equivalent circuit diagram showing various elements and wiring lines of a plurality of pixels arranged in a matrix in the image display region of the liquid crystal device. FIG. 4 is a plan view showing a plurality of pixel groups adjacent to each other on the TFT array substrate having, for example, the data lines, the scanning lines, and the pixel electrodes formed thereon. FIG. 5 is a cross-sectional view taken along the line V-V of FIG. 4. In FIG. 5, the scale of each layer or member is adjusted in order to have a recognizable size in the drawings.

In FIG. 3, the pixel electrode 9a and a TFT 30 for performing switching control on the pixel electrode 9a are formed in each of the plurality of pixel portions arranged in a matrix in the image display region of the liquid crystal display device 1. Sources of the TFTs 30 which are supplied with image signals are electrically connected to data lines 6a. Image signals S1, S2, . . . , Sn to be written onto the data lines 6a are line-sequentially supplied in this order. However, the image signals S1, S2, . . . , Sn may be supplied to each group composed of a plurality of adjacent data lines 6a.

Further, in each of the pixel portions included in the liquid crystal display device 1, a gate of the TFT 30 is electrically connected to a scanning line 3a, and thus scanning signals G1, G2, . . . , Gm are line-sequentially applied to the scanning lines 3a in this order at a predetermined timing in a pulse manner. The pixel electrode 9a is electrically connected to a drain of the TFT 30, and the TFT 30, serving as a switching element, is turned on for a predetermined period, causing the image signals S1, S2, . . . , Sn supplied through the data lines 6a to be written onto the pixel electrodes 9a at a predetermined timing.

The image signals S1, S2, . . . , Sn having predetermined levels which are written onto liquid crystal, serving as an electro-optical material, through the pixel electrodes 9a are stored between the pixel electrodes 9a and the counter electrode formed on the counter substrate for a predetermined period. Storage capacitors 70 for preventing the stored image signals from leaking are electrically connected in parallel to liquid crystal capacitors formed between the pixel electrodes 9a and the counter electrode. The alignment or order of liquid crystal molecules is changed according to the level of a voltage applied, which makes it possible to modulate light and thus to perform grayscale display. In a normally white mode, the transmittance of incident light is lowered according to the voltage applied to each pixel. In a normally black mode, the transmittance of incident light is raised according to the voltage applied to each pixel. Therefore, light having a contrast corresponding to the image signal is emitted from the electro-optical device.

Next, the detailed structure of the pixel portion will be described below with reference to FIGS. 4 and 5. In FIG. 4, a plurality of transparent pixel electrodes 9a(whose outline is represented by a dotted line portion 9a′) arranged in a matrix in the X and Y directions are provided on the TFT array substrate 10. The data lines 6a and the scanning lines 3a are provided along the lengthwise and widthwise boundaries of the pixel electrodes 9a.

The scanning line 3a is disposed so as to be opposite to a channel region 1a′ of a semiconductor layer 1a which is represented by a hatched region on the upper right side of FIG. 4, and the scanning line 3a includes a gate electrode. The pixel switching TFTs 30 are provided at intersections of the scanning lines 3a and the data lines 6a, and a portion of the scanning line 3a, serving as the gate electrode, is arranged opposite to the channel region 1a′.

In FIGS. 4 and 5, the data line 6a is formed on a second interlayer insulating film 42 having a planarized upper surface, serving as an underlayer, and is connected to a heavily doped source region of the TFT 30 through a contact hole 81. The data line 6a and the inside of the contact hole 81 are formed of an aluminum (Al) containing material, such as Al—Si—Cu or Al—Cu, aluminum, or a laminated structure of an Al layer and a Tin layer. The data line 6a also functions as a light shielding firm covering the TFT 30. The underlayer of the data line 6a is formed of a hardening layer 42aa remaining on the second interlayer insulating film 42 when the second interlayer insulating film 42 is formed.

Further, the storage capacitor 70 includes a lower capacitor electrode 71, which is an example of a ‘first electrode’ of this embodiment, a dielectric film 75, and an upper capacitor electrode 300, which is an example of a ‘second electrode’ of this embodiment, and temporally stores the image signal supplied to the pixel electrode 9a through the data line 6a. The lower capacitor electrode 71, serving as a pixel-potential-side capacitor electrode connected to the pixel electrode 9a and a heavily doped drain region 1e of the TFT 30, and a part of the upper capacitor electrode 300, serving as a fixed-potential-side capacitor electrode, are opposite to each other with the dielectric film 75 interposed therebetween.

As shown in FIGS. 4 and 5, the storage capacitor 70 is formed to be separated from the TFT 30 so as not to prevent a hydrogen treatment to be performed on the TFT 30 in a method of manufacturing the liquid crystal display device, which will be described later. More specifically, the upper capacitor electrode 300 extends along the scanning line 3a so as to be provided for all of a plurality of storage capacitors 70 provided in the pixel portions, and the upper capacitor electrode 300 includes a cut-out portion 301 formed on the TFT 30.

In addition, the lower capacitor electrodes 71 are also separated from each other between the pixel portions so as not to overlap each other on the semiconductor layer included in the TFT 30. Therefore, even when the storage capacitor 70 is formed on the upper layer of the TFT 30, the storage capacitor 70 does not prevent the hydrogen treatment to be performed on the TFT 30. Further, the separated portion of the lower capacitor electrode 71 is arranged above the transistor, which makes it unnecessary to excessively reduce the area of the lower capacitor electrode 71 and to largely change the layout of the lower capacitor electrode 71 including, for example, the plan-view shape thereof. As a result, it is possible to reliably perform the hydrogen treatment on the TFT 30, without excessively lowering the capacitance of the storage capacitor 70.

In particular, since the upper capacitor electrode 300 and the lower capacitor electrode 71 are formed of a conductive film transmitting little hydrogen, such as a conductive polysilicon film or a metal film, they are one of main factors preventing the hydrogen treatment. In this embodiment, the upper capacitor electrode 300 and the lower capacitor electrode 71, which are one of the main factors preventing the hydrogen treatment, are formed at positions other than the upper part of the TFT 30, which makes it possible to form the storage capacitor 70, substantially serving as a capacitive element, so as to be separated from the TFT 30.

Therefore, according to the liquid crystal display device 1 of this embodiment, it is possible to form the storage capacitors 70 without largely changing the structure of the liquid crystal display device 1 and a process of manufacturing it, and then perform the hydrogen treatment on the TFTs 30. Also, it is possible to excessively reduce the capacitance of the storage capacitor 70 without a large change in the structure of a liquid crystal display device. In this way, the liquid crystal display device 1 can display high-quality images by using the TFTs 30 whose element characteristics are little lowered, and it is possible to manufacture the liquid crystal display device 1 at high yield. For example, in the liquid crystal display device 1, a wiring layer formed above the TFTs 30 may be charge of a light shielding function for reducing an optical leakage current of the TFTs 30. Even when the wiring layer is formed above the TFTs 30, it is possible to remove the main cause of the lowering of element characteristics of the TFT 30, such as dangling bonding, by performing the hydrogen treatment on the TFT 30 in a stage in which the storage capacitors 70 are formed, and to reduce the amount of light emitted to the TFT 30.

As shown in FIGS. 4 and 5, the upper capacitor electrode 300 is formed of, for example, a conductive light-shielding film containing a metallic material or an alloy, and also functions as a fixed-potential-side capacitor electrode. The upper capacitor electrode 300 is made of, for example, elemental metal including at least one of metallic materials having a high melting point, such as titanium (Ti), chromium (Cr), tungsten (W), tantalum (Ta), molybdenum (Mo), and palladium (Pd), an alloy thereof, a metal silicide, a polysilicide, or a laminate of these materials. The upper capacitor electrode 300 may include metallic materials other than the above-mentioned metallic materials, such as aluminum (Al) and silver (Ag). Alternatively, the upper capacitor electrode 300 may have a multilayer structure of, for example, a first layer composed of a conductive polysilicon film and a second layer composed of a metal silicide film containing a high-melting-point metal.

Meanwhile, the lower capacitor electrode 71 is formed of, for example, a conductive polysilicon film, and serves as the pixel-potential-side capacitor electrode. In addition, the lower capacitor electrode 71 serves as a relay layer for connecting the pixel electrode 9a to the heavily doped drain region 1e of the TFT 30. Similar to the upper capacitor electrode 300, the lower capacitor electrode 71 may be formed of a single-layer film made of a metallic material or an alloy or a multilayer film.

The dielectric film 75 disposed between the lower capacitor electrode 71 and the upper capacitor electrode 300 is composed of, for example, a silicon oxide film, such as a high temperature oxide (HTO) film or a low temperature oxide (LTO) film, or a silicon nitride film. From the viewpoint of increasing the capacitance of the storage capacitor 70, as long as a sufficient degree of is obtained, it is preferable that the thickness of the dielectric film 75 be as small as possible. In addition, the smaller the thickness of the dielectric film 75 becomes, the higher the transmission of hydrogen becomes. Therefore, in order to efficiently perform the hydrogen treatment on the TFT 30, it is preferable that the thickness of the dielectric film 75 be as small as possible.

Further, the upper capacitor electrodes 300 extend from the image display region 10a having the pixel electrodes 9a arranged therein to the periphery thereof to be electrically connected to a constant potential source, thereby having a fixed potential. The constant potential source may be a constant potential source for supplying a positive or negative potential to the scanning line driving circuit 104 or the data line driving circuit 101, or it may be a constant potential source for supplying potential to the counter electrode 21 of the counter substrate 20.

A lower light-shielding film 11a is provided in a lattice shape below the TFTs 30, with a base insulating film 12 interposed therebetween. Since the lower light-shielding film 11a is formed below the TFT 30, the lower light-shielding film 11a does not prevent the hydrogen treatment performed from the upper side of the TFT 30. The light-shielding film 11a is provided to shield the channel region 1a′ of the TFT 30 and the periphery thereof from light incident from the TFT array substrate 10 to the device. Similar to the upper capacitor electrode 300, the lower light-shielding film 11a is formed of, for example, an elemental metal including at least one of metallic materials having a high melting point, such as Ti, Cr, W, Ta, Mo, and Pd, an alloy thereof, a metal silicide, a polysilicide, or a laminate of these materials. In addition, in order to prevent an adverse effect of a change in potential on the TFT 30, the lower light-shielding film 11a may extend from the image display region 10a to the periphery thereof to be connected to the constant potential source, similar to the upper capacitor electrode 300.

The base insulating film 12 has a function of electrically insulating the TFT 30 from the lower light-shielding film 11a, and is provided on the entire surface of the TFT array substrate 10 to prevent characteristics of the pixel switching TFT 30 from being deteriorated due to roughness when the surface of the TFT array substrate 10 is polished or the remnants after cleaning.

The pixel electrode 9a is electrically connected to the heavily doped drain region 1e of the semiconductor layer 1a through contact holes 83 and 85, by using the lower capacitor electrode 71 as a relay layer. That is, in this embodiment, the lower capacitor electrode 71 has a function of connecting the pixel electrode 9a to the TFT 30, in addition to serving as the pixel-potential-side capacitor electrode of the storage capacitor 70. In this way, the structure using the lower capacitor electrode 71 makes it possible to effectively connect two layers by using a contact hole and a groove while overcoming difficulty in connecting two layers with one contact hole, even when a distance between the two layers is relatively large, for example, 2000 nm, and to improve the aperture ratio of the pixel. Therefore, this structure is useful to prevent the layers from being penetrated by etching when the contact hole is formed.

As shown in FIGS. 4 and 5, the liquid crystal display device 1 includes the transparent TFT array substrate 10 and the transparent counter substrate 20 arranged opposite to the TFT array substrate 10. The TFT array substrate 10 is composed of, for example, a quartz substrate, a glass substrate, or a silicon substrate, and the counter substrate 20 is composed of, for example, a glass substrate or a quartz substrate.

The pixel electrodes 9a are provided on the TFT array substrate 10, and an alignment film 16 on which a predetermined alignment process, such as a rubbing process, is performed is provided on the pixel electrodes 9a. The pixel electrodes 9a are formed of, for example, a transparent conductive film, such as an indium tin oxide (ITO) film. Further, the alignment film 16 is composed of, for example, an organic film such as a polyimide film.

The counter electrode 21 is provided on the entire surface of the counter substrate 20. An alignment film 22 on which a predetermined alignment process, such as a rubbing process, is performed is provided below the counter electrode 21. The counter electrode 21 is composed of, for example, a transparent conductive film, such as an ITO film. Further, the alignment film 22 is composed of, for example, an organic film such as a polyimide film.

A lattice-shaped or stripe-shaped light-shielding film may be provided on the counter substrate 20. This structure makes it possible to reliably prevent light incident on the TFT array substrate 10 from passing through the channel region 1a′ and the periphery thereof. Moreover, at least a surface of the light-shielding film formed on the counter substrate 20 is formed to have high reflectance for external light, which makes it possible to prevent an increase in the temperature of the liquid crystal display device 1.

The liquid crystal layer 50 is formed between the TFT array substrate 10 and the counter substrate 20 which are arranged such that the pixel electrodes 9a and the counter electrode 21 face each other. The liquid crystal layer 50 is arranged in a predetermined alignment state by the alignment films 16 and 22 when no voltage is applied from the pixel electrodes 9a.

In FIG. 5, the pixel switching TFT 30 has a lightly doped drain (LDD) structure, and includes the scanning line 3a, the channel region 1a′ of the semiconductor layer 1a in which a channel is formed by an electric field from the scanning line 3a, an insulating film 2 that includes a gate insulating film for electrically insulating the semiconductor layer 1a from the scanning line 3a, a lightly doped source region 1b and a lightly doped drain region 1c of the semiconductor layer 1a, and the heavily doped source region 1d and the heavily doped drain region 1e of the semiconductor layer 1a.

A first interlayer insulating film 41 having the contact hole 81 extending to the heavily doped source region 1d and the contact hole 83 extending to the heavily doped drain region 1e formed therein is formed on the scanning line 3a.

The lower capacitor electrode 71 and the upper capacitor electrode 300 are formed on the first interlayer insulating film 41. The second interlayer insulating film 42 having the contact holes 81 and 85 formed therein is formed on the first interlayer insulating film 41, the lower capacitor electrode 71, and the upper capacitor electrode 300. The second interlayer insulating film 42 is composed of, for example, a BPSG film, and the upper surface of the second interlayer insulating film 42 is fluidized by heating and is then planarized. Step portions are formed on the upper surface of the second interlayer insulating film by the storage capacitor 70, the scanning line 3a, the TFT 30, and the lower light-shielding film 11a when the second interlayer insulting film is formed. However, the fluidization causes the uneven upper surface caused by the step portions to be planarized. The data line 6a and the pixel electrode 9a are formed in a good pattern on the upper surface of the second interlayer insulating film without any remains, which makes it possible for the alignment 16 to perform good alignment. In particular, in recent years, the structure of an electro-optical device becomes complicated in order to prevent an optical current from leaking from the TFT, and the number of layers formed on the substrate increases. In this case, in the related art, a step difference becomes larger as the number of layers becomes larger, and the step difference has a remarkable effect on the formation of the pattern. However, in this embodiment, when the second interlayer insulating film 42 is planarized in this way, it is possible to reduce the overall remains generated by etching on the substrate.

In this embodiment, the upper surface of the second interlayer insulating film 42 is not a completely flat surface, but has a step portion 17a caused by, for example, the scanning lines 3a. The step portion 17a is intentionally formed in order to prevent a transverse electric field, causing a step portion 17 having a predetermined height to be formed on the alignment film 16 in a light-shielding region corresponding to a boundary between the pixels. The step portion 17 functions to weaken a traverse electric field generated between the pixels at the time of driving.

A third interlayer insulating film 43 having the contact holes 85 formed therein is formed so as to cover the data lines 6a and the entire surface of the second interlayer insulating film 42, and is composed of, for example, a BPSG film. Since the data lines 6a containing Al are formed above the third interlayer insulating film 43, a planarizing process by heating is not performed on the third interlayer insulating film 43. The pixel electrodes 9a and the alignment film 16 are formed on the third interlayer insulating film 43.

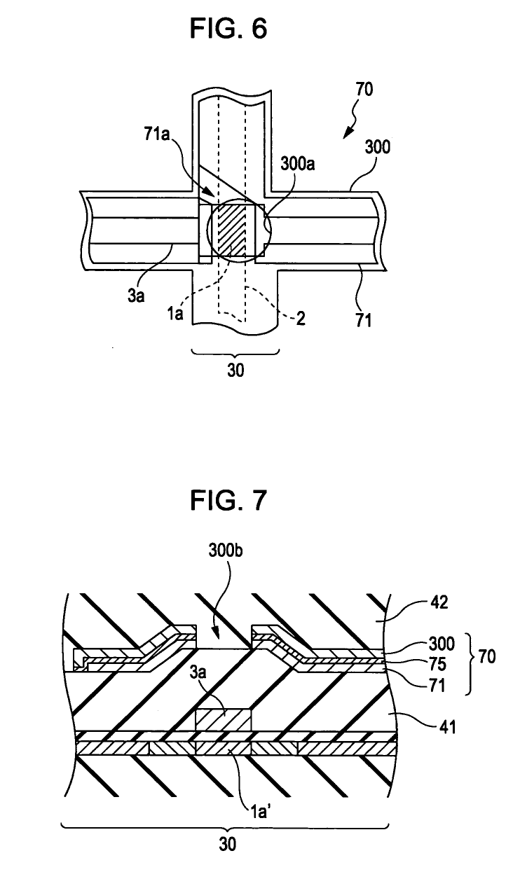

Next, modifications of the storage capacitor 70 will be described with reference to FIGS. 6 and 7. In the following drawings, the same components as those shown in FIGS. 1 to 5 have the same reference numerals, for the purpose of the simplicity of description.

First Modification

The upper capacitor electrode 300 has an opening portion 300a therein, and the lower capacitor electrode 71 has a separating portion 71a arranged between adjacent pixels above the transistor 30.

FIG. 6 is a plan view illustrating the structure of the TFT 30 and the periphery thereof of the liquid crystal display device 1. In FIG. 6, the opening portion 300a is formed by cutting out or patterning a portion of the upper capacitor electrode 300 extending to the upper side of the TFT 30. Therefore, it is possible to prevent the upper capacitor electrode 300 collectively formed so as to be laid across a plurality of pixel portions from hindering the hydrogen treatment from being performed on the TFTs 30, more particularly, on the channel regions 1a′. In addition, the lower capacitor electrode 71 is divided into a plurality of parts above the TFT 30, and the divided electrodes are independently provided in the pixel portions. Therefore, it is possible to perform the hydrogen treatment on the TFT 30 arranged below the lower capacitor electrode 71 through the separating portion 71a.

According to the storage capacitor 70 having the upper capacitor electrode 300 and the lower capacitor electrode 71, it is possible to prevent the element characteristics of the TFT 30 from being deteriorated, without a large reduction in the capacitance of the storage capacitor 70 and a large change in manufacturing processes, and thus to improve display characteristics of the liquid crystal display device 1.

Second Modification

FIG. 7 is a cross-sectional view illustrating the structure of the TFT 30 and the periphery thereof in the section corresponding to FIG. 5. In FIG. 7, in this modification, the upper capacitor electrode 300, the dielectric film 75, and the lower capacitor electrode 71 of the storage capacitor 70 formed on the TFT 30 are separated between adjacent pixel portions to form a separating portion 300b between the separated portions.

According to the storage capacitor 70 included in the liquid crystal display device 1 of this modification, the storage capacitor 70 does not prevent the hydrogen treatment performed on the TFT 30 from the upper side of the storage capacitor 70. More specifically, since the dielectric film 75 is formed so as to be separated from the gate electrode 3a of the TFT 30, that is, the channel region 1a′, it is possible to more efficiently perform the hydrogen treatment on the TFT 30, as compared with a structure in which only the upper capacitor electrode 300 and the lower capacitor electrode 71 are formed so as to be separated from the TFT 30. In particular, since the compact dielectric film 75, such as a silicon nitride film, transmits little hydrogen, the physical separation of the upper capacitor electrode 300, the dielectric film 75, and the lower capacitor electrode 71 between the pixel portions makes it possible to effectively perform the hydrogen treatment on the TFT 30. Instead of separating the dielectric film 75 above the TFT, an opening may be formed in a portion of the dielectric film 75 extending to the upper side of the TFT 30. In this case, the opening also makes it possible to effectively perform the hydrogen treatment on the TFT 30, which obtains the same effect as that obtained from the structure in which the dielectric film 75 is separated above the TFT 30.

(Method of Manufacturing Electro-Optical Device)

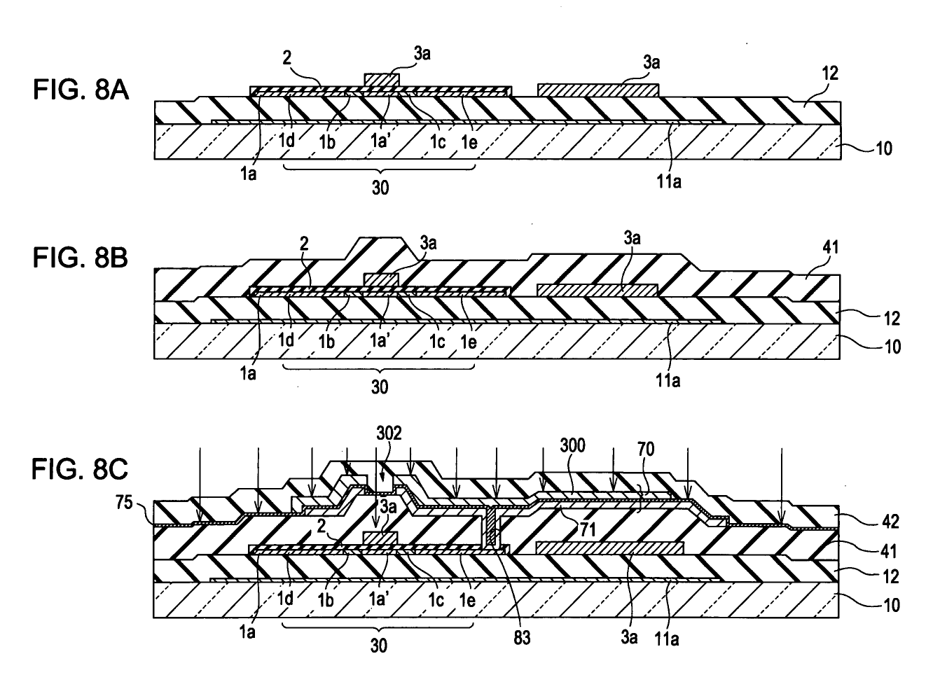

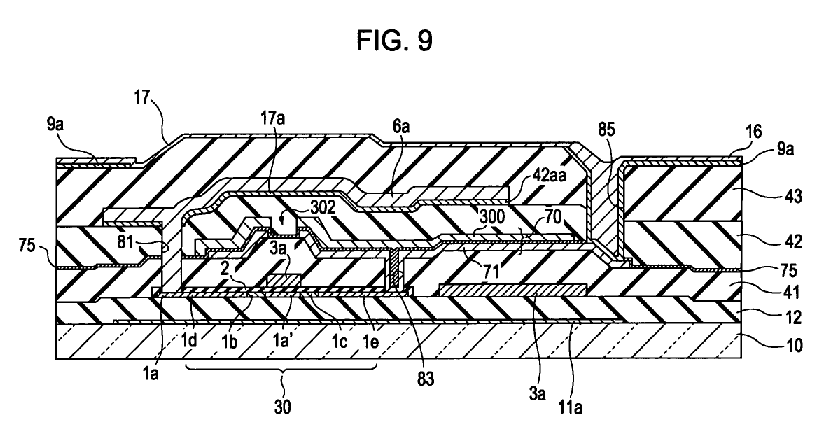

Next, a method of manufacturing the liquid crystal display device according to the above-described embodiment will be described with reference to FIGS. 8A to 8C and FIG. 9. FIGS. 8A to 8C and FIG. 9 are cross-sectional views illustrating the sectional structure shown in FIG. 5 in processes of the manufacturing method. Processes of manufacturing, for example, the data line 6a, the scanning line 3a, the TFT 30, and the storage capacitor 70 of each of the pixel portions formed on the TFT array substrate 10 will be particularly described below in detail, but a description of processes of manufacturing the alignment film 22 and the counter electrode 21 formed on the counter substrate 20 will be omitted.

In FIG. 8A, the TFT array substrate 10, such as a silicon substrate, a quartz substrate, or a glass substrate, is prepared. A heat treatment is performed on the TFT array substrate 10 in an inert gas atmosphere of, for example, N₂ (nitrogen) at a high temperature of about 850 to 1300° C., preferably, 1000° C., and a pre-process is then performed thereon such that the TFT array substrate 10 is less distorted in the subsequent high-temperature process.

Then, a metallic material, such as Ti, Cr, W, Ta, Mo, or Pb, or an alloy, such as a metal silicide, is deposited on the entire surface of the TFT array substrate 10 by means of, for example, a sputtering method, to form a light shielding film having a thickness of 100 nm to 500 nm, and more preferably, about 200 nm. Subsequently, a photolithography process and an etching process are performed thereon to form the lower light-shielding film 11a having a predetermined pattern shown in FIG. 4.

Then, the base insulating film composed of a silicate glass film, such as an NSG (non-silicate glass) film, a PSG (phosphor silicate glass) film, a BSG (boron silicate glass) film, or a BPSG (boron phosphor silicate glass) film, a silicon nitride film, or a silicon oxide film, is formed on the lower light shielding film 11a by, for example, an atmospheric pressure or low pressure CVD method using a TEOS (tetraethyl orthosilicate) gas, a TEB (tetraethyl borate) gas, or a TMOP (tetramethyl oxyphosphate) gas.

Next, an amorphous silicon film is formed on the base insulating film 12 by, for example, a low pressure CVD method. Thereafter, a heat treatment is performed thereon to grow a polysilicon film in a solid state. Alternatively, the polysilicon film is directly formed by, for example, the low pressure CVD method, without performing the process of forming the amorphous silicon film. Then, for example, the photolithography process and the etching process are performed on the polysilicon film to form the semiconductor layer 1a having a predetermined pattern shown in FIG. 4. In addition, the insulating film 2, serving as a gate insulating film is formed by, for example, a thermal oxidation method. As a result, the semiconductor layer 1a has a thickness of about 30 to 150 nm, preferably, 35 to 50 nm, and the insulating film 2 has a thickness of about 20 to 150 nm, preferably, 30 to 100 nm.

Successively, a polysilicon film is formed with a thickness of about 100 to 500 nm by, for example, the low pressure CVD method, and phosphorus (P) is thermally diffused into the polysilicon film to make the polysilicon film conductive. Then, the photolithography method and the etching process are performed thereon to form the scanning lines 3a having a predetermined pattern shown in FIG. 4. Next, impurities are heavily and lightly doped to form the semiconductor layer 1a of the pixel switching TFT 30 having an LDD structure including the lightly doped source region 1b, the lightly doped drain region 1c, the heavily doped source region 1d, and the heavily doped drain region 1e.

In the process shown in FIG. 8B, the first interlayer insulating film 41 is formed, for example, in the same manner as that in which the base insulating film 12 is formed. Although not shown, unevenness corresponding to the shapes of the TFT 30 and the scanning line 3a is formed in the upper surface of the first interlayer insulating film 41.

In the process shown in FIG. 8C, the interlayer insulating film 42 is formed, and the hydrogen treatment is performed on the TFT 30 arranged below the interlayer insulating film 42.

Then, the contact holes 83 are formed in the first interlayer insulating film 41 by, for example, a dry etching method, a wet etching method, or a combination thereof.

Subsequently, a polysilicon film is formed by, for example, the low pressure CVD method, and phosphorus (P) is thermally diffused thereinto to make the polysilicon film conductive, thereby forming the lower capacitor electrode 71. Then, the dielectric film 75 composed of, for example, a high-temperature silicon oxide film (HTO film) or a silicon nitride film is formed with a relatively small thickness of about 50 nm by, for example, the low pressure CVD method, and a metallic material, such as Ti, Cr, W, Ta, Mo, or Pd, or a metal alloy film, such as a metal silicide is deposited thereon by a sputtering method to form the upper capacitor electrode 300. In this way, the storage capacitor 70 is formed.

When the storage capacitor 70 is formed, the lower capacitor electrode 71, the dielectric film 75, and the upper capacitor electrode 300 are annealed at a temperature of 350° C. or more. For example, in this embodiment, the lower capacitor electrode 71 is annealed at a temperature of 850° C., and the dielectric film 75 and the upper capacitor electrode 300 are annealed at a temperature of 500° C. to 850° C. When the annealing process is performed at the above-mentioned temperature range, hydrogen is exhausted from the semiconductor layer of the TFT 30, causing element characteristics, such as dangling bond, to be deteriorated. The exhaustion of hydrogen from the semiconductor layer becomes remarkable at a temperature of 350° C. or more. Therefore, in order to reduce the dangling bond on the TFT 30 without largely changing the outline, structure, and manufacturing processes of the components formed on the TFT array substrate 10, it is important to perform the hydrogen treatment on the TFT 30 after the storage capacitor 70 is formed. In this embodiment, as shown in FIG. 8C, the interlayer insulating film 42 is formed on the storage capacitor through an opening 302 provided in the TFT 30, and then the hydrogen treatment is performed thereon through the opening. The opening portions 300a provided in the upper capacitor electrode 300 and the lower capacitor electrode 71, the separating portion 71a of the lower capacitor electrode 71, or the cut-out portion 301 may be used as the opening 302. In addition, the hydrogen treatment may be performed through the opening 302 and a separating portion of the dielectric film 75 formed above the TFT 30.

Next, as shown in FIG. 9, the data lines 6a each electrically connected to the TFT 30 through the contact hole 81, the third interlayer insulating film 43, the pixel electrodes 9a, and the alignment film 16 are sequentially formed on the TFT array substrate 10 in which the hydrogen treatment is performed on the TFTs 30, thereby forming the TFT array substrate 10 having the main components formed thereon. Then, the liquid crystal layer 5 is interposed between the TFT array substrate 10 and the counter substrate 20, thereby forming the liquid crystal display device 1.

### Second Embodiment

(Detailed Structure of Pixel Portion of Electro-Optical Device)

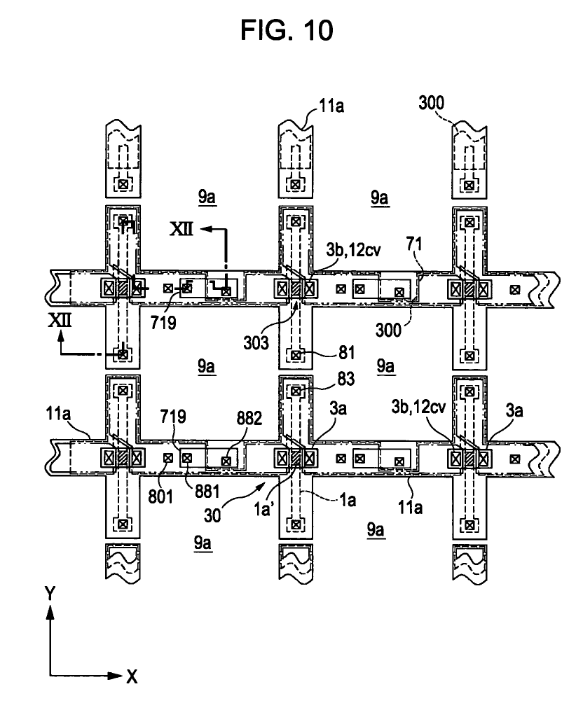

Next, the detailed structure of a pixel portion of a liquid crystal display device 1 according to this embodiment will be described with reference to FIGS. 10 to 12. In this embodiment, the hydrogen treatment is performed on TFTs 30 included in the liquid crystal display device 1 after storage capacitors 70 are formed, similar to the first embodiment. Therefore, in this embodiment, it is possible to prevent element characteristics of the TFT 30 from being deteriorated and thus to obtain a high-quality liquid crystal display device.

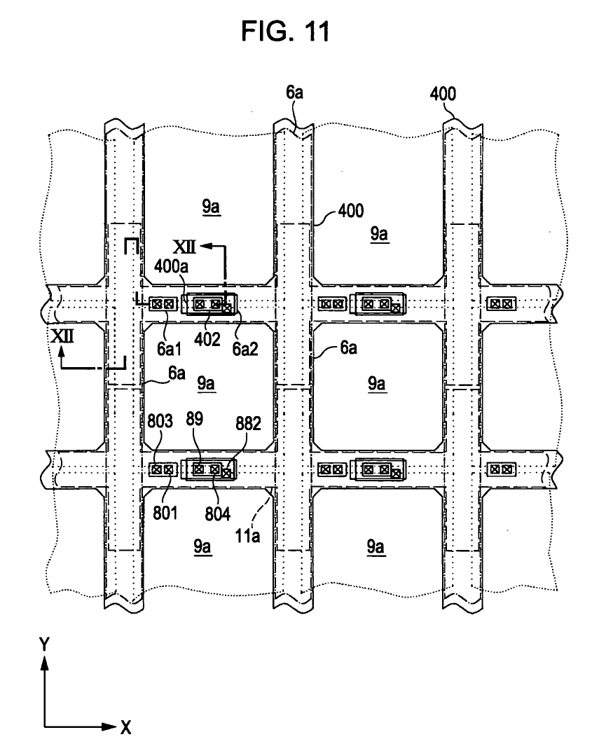

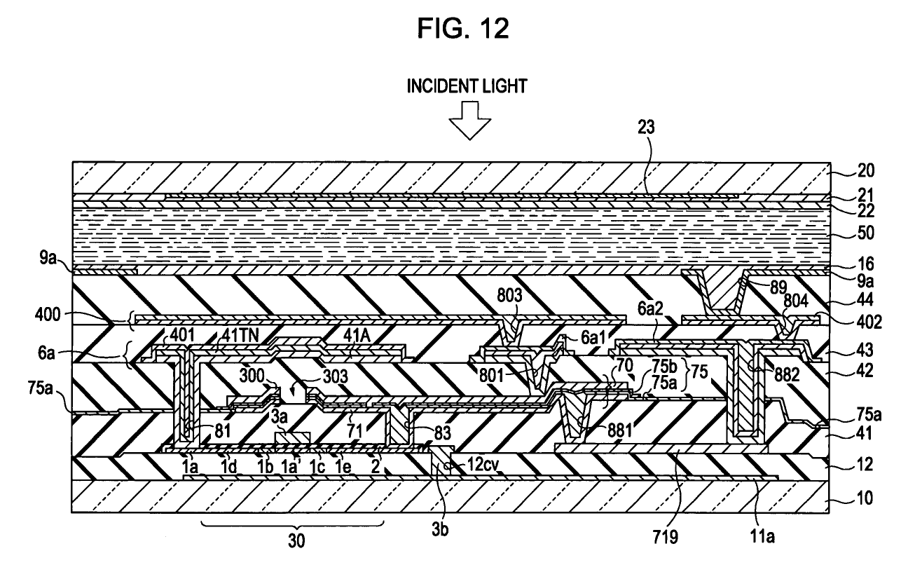

FIGS. 10 and 11 are plan views showing a plurality of pixel groups adjacent to each other on a TFT array substrate having, for example, data lines, scanning lines, and pixel electrodes formed thereon. More specifically, FIG. 10 is a plan view illustrating a lower layer portion of a laminated structure, which will be described later, and FIG. 11 is a plan view illustrating an upper layer portion of the laminated structure. FIG. 12 is a cross-sectional view taken along the line XII-XII′ of FIGS. 10 and 11. In FIG. 12, the scale of each layer or member is adjusted in order to have a recognizable size in the drawings. In this embodiment, a description of the electrical structure of a pixel display region and the same components as those in the first embodiment will be omitted for the purpose of simplicity.

As shown in FIG. 12, a laminated structure of various components including the pixel electrodes 9a and the alignment film 16 is formed on the TFT array substrate 10 of the liquid crystal display device according to this embodiment. More specifically, the TFT array substrate includes a first layer including the scanning lines 11a, a second layer including, for example, the TFTs 30 has gate electrodes 3a, a third layer including the storage capacitors 70, a fourth layer including, for example, data lines 6a, a fifth layer including, for example, capacitor wiring lines 400, and a sixth layer (the uppermost layer) including, for example, the pixel electrodes 9a and the alignment film 16 sequentially formed from the bottom thereof. A base insulating film 12 is provided between the first layer and the second layer, and a first interlayer insulating film 41 is provided between the second layer and the third layer. A second interlayer insulating film 42 is provided between the third layer and the fourth layer, and a third interlayer insulating film 43 is provided between the fourth layer and the fifth layer. A fourth interlayer insulating film 44 is provided between the fifth layer and the sixth layer. In this way, the first to sixth layers are insulated from one another. In addition, for example, contact holes, each electrically connecting a heavily doped source region 1d of a semiconductor layer 1a of the TFT 30 to the data line 6a, are provided in the insulating films 12, 41, 42, 43, and 44. Hereinafter, these components will be sequentially described from the lower component. The first to third layers are included in the lower layer portion shown in FIG. 10, and the fourth to sixth layers are included in the upper layer portion shown in FIG. 11.

(Laminated Structure: Structure of First Layer—Scanning Lines, etc.)

First, the first layer is provided with the scanning lines 11a formed of, for example, a metallic material having a high melting point, such as Ti, Cr, W, Ta, or Mo, an alloy thereof, metal silicide, polysilicide, a laminated structure thereof, or conductive polysilicon. The scanning lines 11a are patterned in strip shapes extending in the X direction of FIG. 10 in plan view. More specifically, the strip-shaped scanning line 11a includes a main body portion extending in the X direction of FIG. 10 and a protruding portion extending in the Y direction of FIG. 10 in which the data line 6a or the capacitor wiring line 400, which is an example of a ‘wiring portion’ of the invention, extend. The protruding portions extending adjacent scanning lines 11a are not connected to each other, so that the scanning lines 11a are separated from one another.

FIGS. 10 and 11 show the structure of the scanning lines 11a. In this embodiment, as shown in FIG. 11, the scanning lines 11a overlap the capacitor wiring lines 400 on the TFT array substrate 10 in plan view. The detailed structure of the scanning lines 11a will be described later.

(Laminated Structure: Structure of Second Layer—TFTs, etc.)

Next, the TFTs 30 including the gate electrodes 3a are provided in the second layer. As shown in FIG. 12, the TFT 30 has an LDD (lightly doped drain) structure. The TFT 30 includes the gate electrode 3a, a channel region 1a′ of the semiconductor layer 1a which is formed of, for example, a polysilicon film and whose channel is formed by an electric field from the gate electrode 3a, an insulating film 2 that includes a gate insulating film for electrically insulating the semiconductor layer 1a from the gate electrode 3a, a lightly doped source region 1b and a lightly doped drain region 1c of the semiconductor layer 1a, and a heavily doped source region 1d and a heavily doped drain region 1e of the semiconductor layer 1a.

In this embodiment, a relay electrode 719 is formed in the second layer by using the same film as that used for the gate electrode 3a. As show in FIG. 10, the relay electrode 719 is formed in an island shape in plan view so as to be arranged substantially in the center of one side of the pixel electrode 9a extending in the X direction. In this embodiment, the relay electrode 719 and the gate electrode 3a are formed by the same film. That is, when the latter is composed of a conductive polysilicon film, the former is also composed of a conductive polysilicon film.

It is preferable that the TFT 30 have an LDD structure as shown in FIG. 12. Alternatively, the TFT 30 may have an offset structure in which no impurity is doped into the lightly doped source region 1b and the lightly doped drain region 1c, or it may have a self-alignment structure in which impurities are doped at high concentration using the gate electrode 3a as a mask to form a heavily doped source region and a heavily doped drain region in a self-alignment manner.

(Laminated Structure: Structure between First and Second Layers—Base Insulating Film)

The base insulating film 12 composed of, for example, a silicon oxide film is provided between the above-mentioned scanning lines 11a and the TFTs 30. The base insulating film 12 has a function of insulating the TFT 30 from the scanning line 11a. Further, since the base insulating film 12 is formed on the entire surface of the TFT array substrate 10, it has a function of preventing a change in the characteristics of the pixel switching TFT 30 due to roughness when the surface of the TFT array substrate is polished or contaminants remaining after cleaning.

In the base insulating film 12, contact holes 12cv, each extending in the lengthwise direction of the channel of the semiconductor layer 1a which extends along the data line 6a, which will be described later, are formed at both sides of the semiconductor layer 1a in plan view. The gate electrode 3a formed on the base insulating film 12 includes a portion whose lower surface is concave to correspond to the contact hole 12cv. Further, the gate electrode 3a is formed so as to fill up the contact hole 12cv, causing a side wall portion 3b integrally formed with the gate electrode 3a to extend from the gate electrode 3a. Thus, as shown in FIG. 10, the semiconductor layer 1a of the TFT 30 is covered from sides in plan view, which prevents light from being incident on at least the side portions.

Further, the side wall portion 3b is formed to fill up the contact hole 12cv, and the lower end of the side wall portion 3b contact the scanning line 11a. Since the scanning line 11a is formed in a strip shape, as described above, the gate electrode 3a and the scanning line 11a arranged in the same row have the same potential, considering only the corresponding row.

(Laminated Structure: Structure of Third Layer—Storage Capacitors, etc.)

The storage capacitor 70 is provided in the third layer above the second layer. The storage capacitor 70 is formed by arranging the lower capacitor electrode 71, serving as a pixel potential side capacitor electrode, connected to the heavily doped drain region 1e of the TFT 30 and the pixel electrode 9a so as to be opposite to the upper capacitor electrode 300, serving as a fixed potential side capacitor electrode, with the dielectric film 75 interposed therebetween. The storage capacitor 70 makes it possible to remarkably improve potential storing characteristics of the pixel electrode 9a. Further, as can be seen from the plan view of FIG. 10, the storage capacitor 70 is formed so as not to reach a light transmitting region substantially corresponding to a region where the pixel electrode 9a is formed (that is, the storage capacitor 70 is formed in a light-shielding region). Thus, the pixel aperture ratio of the entire electro-optical device can be kept relatively high, which makes it possible to display a bright image.

More specifically, the lower capacitor electrode 71 is composed of, for example, a conductive polysilicon film and serves as the pixel potential side capacitor electrode. However, the lower capacitor electrode 71 may be formed of a single-layered film made of a metallic material or an alloy thereof or a multilayered film. In addition to the function of the pixel potential side capacitor electrode, the lower capacitor electrode 71 has a function of connecting the pixel electrode 9a to the heavily doped drain region 1e of the TFT 30. The connection therebetween is made by the relay electrode 719.

The upper capacitor electrode 300 is electrically connected to the capacitor wiring line 400 (which will be described later) having a fixed potential, so that the capacitor electrode 300 has the fixed potential.

In this embodiment, the upper capacitor electrode 300 may serve as the pixel potential side capacitor electrode and the lower capacitor electrode 71 may serve as the fixed potential side capacitor electrode by changing the outlines of the components formed on the TFT array substrate 10 a little.

As shown in FIG. 12, the dielectric film 75 is composed of, for example, a silicon nitride film or a silicon oxide film, such as a HTO (high temperature oxide) film or an LTO (low temperature oxide) film having a relatively small thickness of about 5 to 200 nm.

In this embodiment, as shown in FIG. 12, the dielectric film 75 has a two-layered structure of a lower silicon nitride film 75a and an upper silicon nitride film 75b. The upper silicon nitride film 75b is patterned in a size slightly larger than that of the lower capacitor electrode 71, serving as the pixel potential side capacitor electrode, such that it comes within a light shielding region (a non-opening region).

In this embodiment, the dielectric film 75 has the two-layered structure. However, the dielectric film 75 may have a three-layered structure of, for example, a silicon oxide film, a silicon nitride film and a silicon oxide film or laminated structures other than the three-layered structure. It goes without saying that the dielectric film 75 may have a single-layered structure.

An opening 303 is formed in the upper capacitor electrode 300 and the lower capacitor electrode 71 of the storage capacitor 70 above the TFT 30. The opening 303 formed in the upper capacitor electrode 300 and the lower capacitor electrode 71 and a separating portion of the entire capacitor insulating film are arranged above the TFT 30. A cut-out portion or an opening may be formed in the upper capacitor electrode 300. An opening may be formed in the capacitor insulating film. When a film having low hydrogen transmission, such as a nitride film, is not included in the capacitor insulating film, the opening or the separating film is not provided above the transistor, which is preferable. The opening 303 makes it possible to perform the hydrogen treatment on the TFT 30 formed below the storage capacitor 70 after the storage capacitor 70 is formed. The opening 303 may include the opening or the separating portion formed in the dielectric film 75.

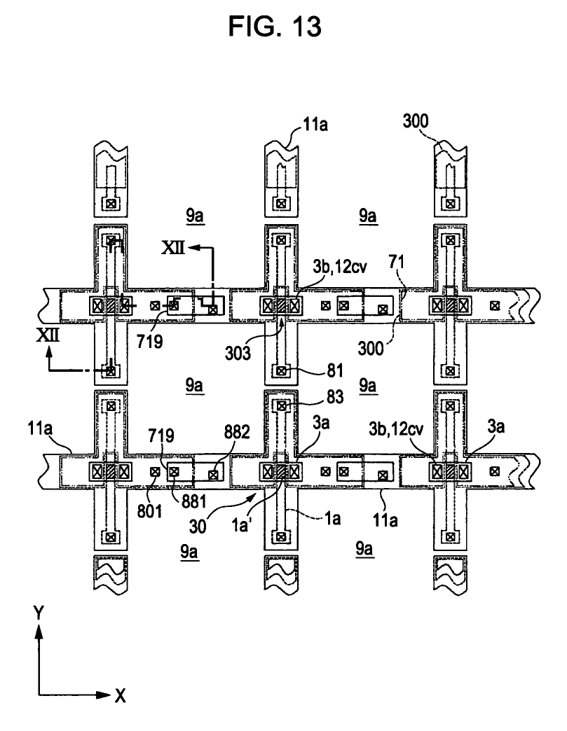

The plan-view layout of the liquid crystal display device 1 shown in FIG. 12 may be changed as shown in FIG. 13. That is, the separating portion may be arranged at positions other than the upper side of the transistor 30 (the right or left side of a contact hole 882 in FIG. 13), and a cut-out portion 303 may be formed in the upper capacitor electrode 300, the lower capacitor electrode 71, and capacitor insulating films 75a and 75b above the TFT 30.

(Laminated Structure: Structure between Second Layer and Third Layer—First Interlayer Insulating Film)

The first interlayer insulating film 41 composed of, for example, a silicate glass film, such as an NSG (non-silicate glass) film, a PSG (phosphor silicate glass) film, a BSG (boron silicate glass) film, or a BPSG (boron phosphor silicate glass) film, a silicon nitride film, or a silicon oxide film, or preferably, the NSG film is formed on the TFT 30, the gate electrode 3a, and the relay electrode 719 and below the storage capacitor 70.

The contact holes 81 each electrically connecting the heavily doped source region 1d of the TFT 30 to the data line 6a, which will be described later, are formed in the first interlayer insulating film 41 and the second interlayer insulating film 42. Contact holes 83, each electrically connecting the heavily doped drain region 1e of the TFT 30 to the storage capacitor 71, are formed in the first interlayer insulating film 41. In addition, contact holes 881, each electrically connecting the relay electrode 719 to the lower capacitor electrode 71 serving as the pixel potential side capacitor electrode of the storage capacitor 70, are formed in the first interlayer insulating film 41. Further, contact holes 882, each electrically connecting the relay electrode 719 to a second relay electrode 6a2, which will be described later, are formed in the first interlayer insulating film 42 and the second interlayer insulating film 42.

(Laminated Structure: Structure of Fourth Layer—Data Lines, etc.)

The data lines 6a are provided in the fourth layer above the third layer. As shown in FIG. 12, the data line 6a is composed of a three-layered film of a layer formed of aluminum (see reference numeral 41A in FIG. 12), which is the lowest layer, a layer formed of titanium nitride (see reference numeral 41TN in FIG. 12), and a layer formed of a silicon nitride film (see reference numeral 401 in FIG. 12), which is the uppermost layer. The silicon nitride film is patterned in a size slightly larger than those of the aluminum layer and the titanium nitride, so that it covers the aluminum layer and the titanium nitride.

A capacitor line relay layer 6al and second relay electrodes 6a2 are formed by the same film as that used for the data lines 6a in the fourth layer. As shown in FIG. 11, the capacitor line relay layer 6a1 and the second relay electrode 6a2 are formed so as not to be connected to the data line 6a in plan view, but so as to be separated from the data line 6a in pattern.

Since the capacitor line relay layer 6a1 and the second relay electrode 6a2 are formed by the same film as that used for the data line 6a, they have a three-layered structure of a layer formed of aluminum, which is the lowest layer, a layer formed of titanium nitride, and a layer formed of a plasma nitride film, which is the uppermost layer.

(Laminated Structure: Structure between Third Layer and Fourth Layer—Second Interlayer Insulating Film)

The second interlayer insulating film 42 composed of a silicate glass film, such as an NSG film, a PSG film, a BSG film, or a BPSG film, a silicon nitride film, or a silicon oxide film is formed on the storage capacitors 70 and below the data lines 6a by, for example, a plasma CVD method using a TEOS gas. The contact holes 81, each electrically connecting the heavily doped source region 1d of the TFT 30 to the data line 6a, and contact holes 801, each electrically connecting the capacitor line relay layer 6a1 to the upper capacitor electrode 300 of the storage capacitor 70, are formed in the second interlayer insulating film 42. In addition, the contact holes 882, each electrically connecting the second relay electrode 6a2 to the relay electrode 719, are formed in the second interlayer insulating film 42.

(Laminated Structure: Structure of Fifth Layer—Capacitor Wiring Lines, etc.)

The capacitor wiring lines 400 are formed in the fifth layer 5 above the fourth layer. The capacitor wiring lines 400 are formed in a lattice shape extending in the X and Y directions in plan view, as described in FIG. 11. The capacitor wiring lines 400 define opening regions of the pixels. Since the capacitor wiring lines 400 are formed after the hydrogen treatment is performed on the TFTs 30, the capacitor wiring lines 400 does not prevent the hydrogen treatment on the TFTs 30 even when they are formed so as to extend onto the TFTs 30.

In particular, a portion of the capacitor wiring line 400 extending in the Y direction of FIG. 11 is formed to have a larger width than that of the data line 6a such that it covers the data line 6a. In addition, in order to ensure a region required for forming the third relay electrode 402, a window 400a, which is an opening portion formed so as to be separated from the opening region, is provided in a portion of the capacitor wiring line 400 extending in the X direction of FIG. 11 in the vicinity of the center of one side of each pixel electrode 9a.

In FIG. 11, substantially triangular portions are provided at corners of intersections between the capacitor wiring lines 400 extending in the X and Y direction to cover the corners. The substantially triangular portions provided in the capacitor wiring lines 400 make it possible to effectively shield light from the semiconductor layer 1a of the TFT 30. That is, light obliquely incident on the semiconductor layer 1a is reflected from or absorbed by the substantially triangular portions, so that no light is incident on the semiconductor layer 1a. Therefore, it is possible to prevent an optical current from leaking and thus to display a high-quality image without flicker. The capacitor wiring lines 400 extend from the image display region 10a having the pixel electrodes 9a arranged therein to the periphery thereof to be electrically connected to a fixed potential source, thereby having a fixed potential.

In the fifth layer, each of the third relay electrodes 402 formed of the same film as that used for the capacitor wiring lines 400 is formed in an island shape in the window 400a of the capacitor wiring line 400. More specifically, the capacitor wiring line 400 and the third relay electrode 402 are formed so as not to be connected to each other in plan view, but so as to be separated from each other in pattern. In this way, the third relay electrode 402 can be electrically separated from the capacitor wiring line 400. The third relay electrode 402 has a function of relaying electrical connection between the second relay electrode 6a2 and the pixel electrode 9a through contact holes 804 and 89. The capacitor wiring line 400 and the third relay electrode 402 have a two-layered structure of a lower layer formed of aluminum and an upper layer formed of titanium nitride.

(Laminated Structure: Structure between Fourth Layer and Fifth Layer—Third Interlayer Insulating Film)

The third interlayer insulating film 43 composed of a silicate glass film, such as an NSG film, a PSG film, a BSG film, or a BPSG film, a silicon nitride film, or a silicon oxide film is formed on the data lines 6a and below the capacitor wiring lines 400 by, for example, a plasma CVD method using a TEOS gas. Contact holes 81, each electrically connecting the capacitor wiring line 400 to the capacitor line relay layer 6a1, and contact holes 804, each electrically connecting the third relay electrode 402 to the second relay electrode 6a2, are formed in the third interlayer insulating film 43.

(Laminated Structure: Structure of Sixth Layer and Structure between Fifth Layer and Sixth Layer—Pixel Electrodes, etc.)

Finally, the pixel electrodes 9a are formed in a matrix in the sixth layer, and the alignment film 16 is formed on the pixel electrodes 9a. A fourth interlayer insulating film 44 composed of, for example, a silicate glass film, such as an NSG film, a PSG film, a BSG film, or a BPSG film, a silicon nitride film, or a silicon oxide film, or preferably, the NSG film is formed below the pixel electrodes 9a. The contact holes 89, each electrically connecting the pixel electrode 9a to the third relay electrode 402, are formed in the fourth interlayer insulating film 44. The pixel electrode 9a and the TFT 30 are electrically connected to each other through the contact hole 89, the third relay layer 402, the contact hole 804, the second relay layer 6a2, the contact hole 882, the relay electrode 719, the contact hole 881, the lower capacitor electrode 71, and the contact hole 83.

A liquid crystal display device is composed of the TFT array substrate 10, the counter substrate 20, and the liquid crystal layer interposed between these substrates having the above-described structures. According to the liquid crystal display device of this embodiment, it is possible to prevent element characteristics of the TFT 30 from being deteriorated due to the transmission of hydrogen, without a large change in the structure of the device and manufacturing processes, and thus to provided a high-quality liquid crystal display device. Even when the light shielding film 23 is not formed on the counter substrate 20, it is possible to reliably shield light incident from the counter substrate 20 and light incident from the element substrate 10 by using the capacitor wiring lines 400, the third relay electrodes 402, and the scanning lines 11a. Therefore, according to the liquid crystal display device of the invention, it is possible to display images having high contrast and high definition.

Electronic Apparatus

Next, various electronic apparatus equipped with the above-described liquid crystal display device will be described below.

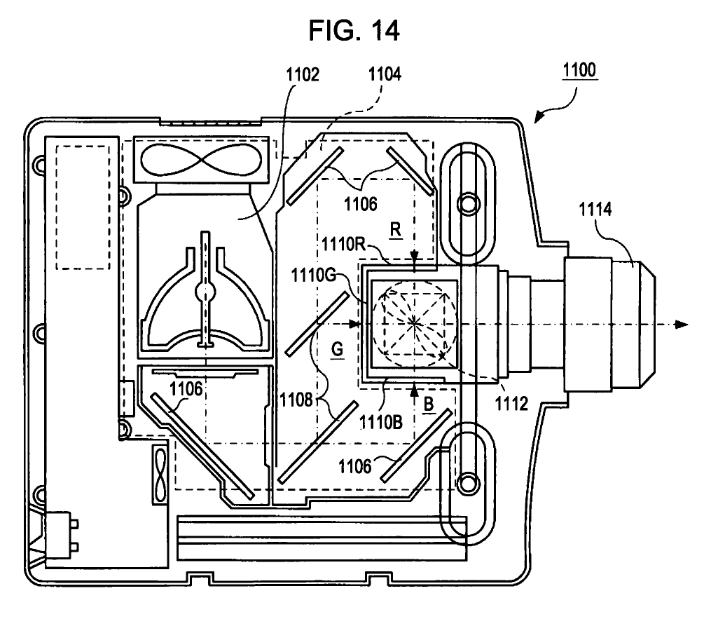

First, a projector using the liquid crystal display devices as light valves will be described. FIG. 14 is a plan view illustrating the structure of the projector. As shown in FIG. 14, a lamp unit 1102 composed of a white light source, such as a halogen lamp, is provided in a projector 1100. Projection light emitted from the lamp unit 1102 is separated into light components corresponding to the three primary colors R (red), G (green), and B (blue) by four mirrors 1106 and two dichroic mirrors 1108 which are arranged in a light guide 1104, and the light components are respectively incident on liquid crystal panels 1110R, 1110B, and 1110G, serving as light valves corresponding to the three primary colors.

The structures of the liquid crystal panels 1110R, 1110B, and 1110G are the same as that of the above-mentioned liquid crystal display device, and the liquid crystal panels 1110R, 1110B, and 1110G are respectively driven by R, G, and B signals supplied from an image signal processing circuit. Then, the light components modulated by these liquid crystal panels are incident on a dichroic prism 1112 in three directions. In the dichroic prism 1112, the R and B light components are refracted at an angle of 90°, and the G light component travels straight. Then, the three color images are combined into a color image, and the color image is projected onto, for example, a screen through a projection lens 1114.

Here, paying attention to the images displayed by the liquid crystal panels 1110R, 1110G, and 1110B, it is necessary to reverse the right and left sides of the image displayed by the liquid crystal panel 1110G with respect to the images displayed by the liquid crystal panels 1110R and 1110B.

Further, since the light components corresponding to the three primary colors R, G, and B are incident on the liquid crystal panels 1110R, 1110B, and 1110G by the dichroic mirrors 1108, color filters are not needed.

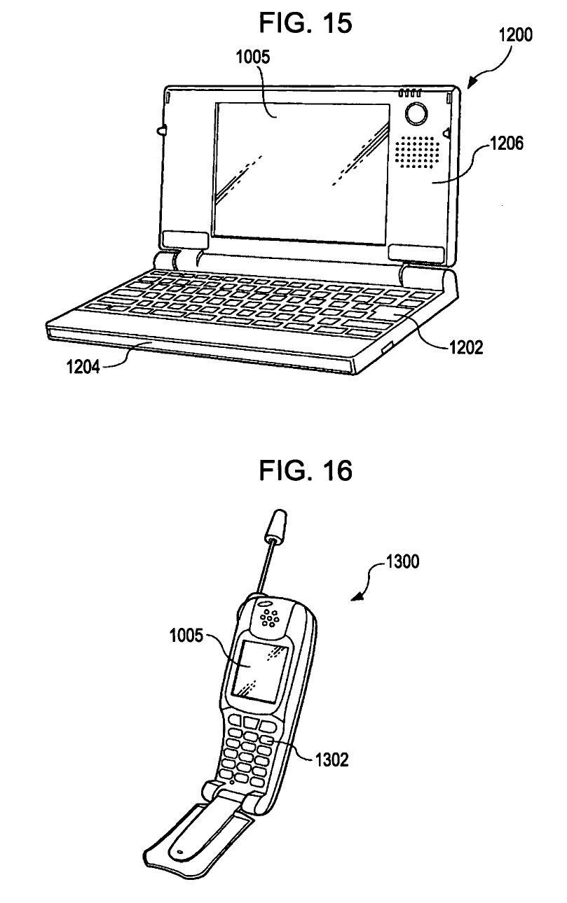

Next, an example in which the liquid crystal display device is applied to a portable personal computer will be described. FIG. 15 is a perspective view showing the structure of the personal computer. In FIG. 15, a computer 1200 includes a main unit 1204 including a keyboard 1202 and a liquid crystal display unit 1206. The liquid crystal display unit 1206 includes a liquid crystal display device 1005 and a back light provided on the rear surface of the liquid crystal display device 1005.

Next, an example in which the liquid crystal display device is applied to a cellular phone will be described. FIG. 16 is a perspective view showing the structure of the cellular phone. In FIG. 16, a cellular phone 1300 includes a plurality of operating buttons 1302 and a reflective liquid crystal display device 1005. A front light is provided on the front surface of the reflective liquid crystal device 1005, if necessary.

In addition to the electronic apparatuses described with reference to FIGS. 14 to 16, the liquid crystal display device according to the invention can be applied to various electronic apparatuses, such as a liquid crystal television, a view-finder-type or monitor-direct-view-type videotape recorder, a car navigation apparatus, a pager, an electronic organizer, an electronic calculator, a word processor, a workstation, a television phone, a POS terminal, and apparatuses equipped with touch panels.

It is to be understood that the invention is not limited to the above-described embodiments and various modifications and changes can be made without departing from the scope and spirit of the invention as defined by the appended claims and the entire specification. Therefore, a method of manufacturing an electro-optical device, an electro-optical device, an electronic apparatus, and a method of manufacturing a semiconductor substrate according to the modifications of the invention are also included in the technical scope of the invention. More specifically, the electro-optical device or the electronic apparatus of the invention can be applied to, for example, various transmissive, reflective, and self-emitting devices, such as an LCOS (liquid crystal on silicon) device, a DMD (digital micro mirror device), and an organic EL device.

What is claimed is:

1. An electro-optical device comprising:
a substrate;
a plurality of data lines which are formed on the substrate;
a plurality of scanning lines which are arranged on the substrate so as to intersect the plurality of data lines;
a plurality of pixel electrodes which are provided on the substrate so as to correspond to intersections of the plurality of data lines and the plurality of scanning lines;
a plurality of transistors which are formed on the substrate so as to be electrically connected to the plurality of pixel electrodes; and
a plurality of storage capacitors each of which is provided above the transistor so as not to be in contact with the transistor in plan view and temporally stores a pixel signal supplied to the pixel electrode through the data line and the transistor,
wherein a separating region between adjacent storage capacitors among the plurality of storage capacitors is arranged above the transistor.

2. The electro-optical device according to claim 1,
wherein the separating region is arranged above at least a channel region of the transistor.

3. The electro-optical device according to claim 1,
wherein the separating region is arranged above at least the channel region and an LDD region of the transistor.

4. The electro-optical device according to claim 1,
wherein each of the storage capacitors includes a first electrode formed above the transistor, a dielectric film formed on the first layer, and a second layer formed on the dielectric film, and
at least the first and second electrodes of the first electrode, the second electrode, and the dielectric film are formed so as not to be in contact with the transistor in plan view.

5. The electro-optical device according to claim 4,
wherein the second electrode extends along the scanning line so as to be provided for all of the plurality of storage capacitors, and
a portion of the second electrode is cut out so that the second electrode does not overlap the transistor in plan view.

6. The electro-optical device according to claim 4,
wherein the second electrode extends along the scanning line so as to be provided for all of the plurality of storage capacitors, and
the second electrode has a first opening portion which is formed so as to overlap the transistor in plan view.

7. The electro-optical device according to claim 6,
wherein the second electrode is a pixel-potential-side capacitor electrode, and
the separating portion of the capacitor electrode is arranged above the transistor, so that the transistor is exposed through the storage capacitor.

8. The electro-optical device according to claim 4, further comprising:
wiring portions which are formed above the storage capacitors on the substrate so as to be electrically connected to the second electrodes,
wherein each of the wiring portions is formed so as to extend on the storage capacitor, after a hydrogen treatment is performed on a semiconductor layer of the transistor from the upper side of the storage capacitor.

9. The electro-optical device according to claim 4,
wherein the dielectric film is formed so as not to be in contact with the transistor in plan view.

10. The electro-optical device according to claim 9,
wherein the dielectric film is physically separated between the storage capacitors so as not to overlap the transistor in plan view.

11. The electro-optical device according to claim 4,
wherein the dielectric film extends on the substrate so as to be provided for all of the plurality of storage capacitors, and
the dielectric film has a second opening portion which is formed so as to overlap the transistor in plan view.

12. A method of manufacturing an electro-optical device, comprising:
forming a plurality of data lines and a plurality of scanning lines on a substrate so as to intersect each other;
forming a plurality of pixel electrodes on the substrate so as to correspond to intersections of the plurality of data lines and the plurality of scanning lines;
forming a plurality of transistors on the substrate so as to be electrically connected to the plurality of pixel electrodes; and
forming a plurality of storage capacitors, each temporally storing an image signal supplied to the pixel electrode through the data line and the transistor, above the transistors so as not to be in contact with the transistors in plan view,
wherein in the forming of the storage capacitors, a first electrode, a dielectric film, and a second electrode are sequentially formed above each of the transistors to form the storage capacitor, and
the first electrode and the second electrode are formed so as not to be in contact with the transistor in plan view.

13. The method of manufacturing an electro-optical device according to claim 12,
wherein the forming of the storage capacitors includes annealing the first electrode, the dielectric film, and the second electrode at a temperature of 350° C. or more, and
after the annealing, a hydrogen treatment is performed on a semiconductor layer of the transistor from the upper side of the storage capacitor.

14. An electronic apparatus comprising the electro-optical device according to claim 1.
